(19) United States
(12) Patent Application Publication
(10) Pub. No.: US 2017/0345823 A1
(43) Pub. Date: Nov. 30, 2017

(54) ELECTRONIC DEVICE AND METHOD FOR FABRICATING THE SAME

(71) Applicant: SK hynix Inc., Icheon (KR)

(72) Inventor: Bong-Hoon JANG, Icheon (KR)

(21) Appl. No.: 15/416,914

(22) Filed: Jan. 26, 2017

(30) Foreign Application Priority Data
May 25, 2016 (KR) 10-2016-0063890

(51) Int. Cl. H01L 27/108

(52) U.S. Cl. CPC H01L 27/10829; H01L 27/10861

(57) ABSTRACT

An electronic device includes a semiconductor memory. The semiconductor memory may include a semiconductor substrate having an isolation trench in a first region and a capacitor trench in a second region, an isolation layer filling the isolation trench, an insulation layer pattern disposed along the capacitor trench, and a conductive layer pattern filling the capacitor trench over the insulation layer pattern. A capacitor includes a first portion of the semiconductor substrate in the second region, the insulation layer pattern, and the conductive pattern. A sidewall of the capacitor trench has a first angle with respect to a surface of the semiconductor substrate and a sidewall of the isolation trench has a second angle with respect to the surface of the semiconductor substrate. The first angle is more proximate to 90 degrees than the second angle.

### CROSS-REFERENCE TO RELATED APPLICATIONS

The present application claims priority of Korean Patent Application No. 10-2016-0063890, entitled “ELECTRONIC DEVICE AND METHOD FOR FABRICATING THE SAME” and filed on May 25, 2016, which is incorporated herein by reference in its entirety.

### TECHNICAL FIELD

This patent document relates to memory circuits or devices and their applications in electronic devices or systems.

### BACKGROUND

Recently, as electronic appliances trend toward miniaturization, low power consumption, high performance, multi-functionality, and so on, demand for semiconductor devices capable of storing information in various electronic appliances such as a computer, a portable communication device, and so on has been increasing, and a lot of research has been conducted for semiconductor devices. Such semiconductor devices include semiconductor devices which can store data by switching between different states according to an applied voltage or current, such as, for example, an RRAM (resistive random access memory), a PRAM (phase change random access memory), an FRAM (ferroelectric random access memory), an MRAM (magnetic random access memory), an E-fuse, and the like.

### SUMMARY

The disclosed technology in this patent document includes memory circuits or devices and their applications in electronic devices or systems and various implementations of an electronic device which may satisfy both characteristics of an isolation layer and a trench-type capacitor, and a method for fabricating the electronic device.

In an implementation, an electronic device may be provided. The electronic device may include a semiconductor memory. The semiconductor memory may include: a semiconductor substrate having an isolation trench in a first region and a capacitor trench in a second region; an isolation layer filling the isolation trench; an insulation layer pattern disposed along the capacitor trench; and a conductive layer pattern filling the capacitor trench over the insulation layer pattern, wherein a capacitor includes a first portion of the semiconductor substrate in the second region, the insulation layer pattern, and the conductive pattern, and wherein a sidewall of the capacitor trench has a first angle with respect to a surface of the semiconductor substrate and a sidewall of the isolation trench has a second angle with respect to the surface of the semiconductor substrate, the first angle being more proximate to 90 degrees than the second angle.

Implementations of the above device may include one or more the following.

Upper edges of the capacitor trench are more rounded than upper edges of the isolation trench. A bottom surface of the capacitor trench is disposed lower than a bottom surface of the isolation trench. The isolation trench has a width that decreases when it approaches from a top surface to a bottom surface of the isolation trench, and wherein the capacitor trench has a substantially uniform width along a direction from a top surface to a bottom surface of the capacitor trench. The semiconductor memory further includes: a gate insulation layer and a gate electrode disposed over a second portion of the semiconductor substrate in the first region. The gate insulation layer includes the same material as the insulation layer pattern, and the gate electrode includes the same material as the conductive layer pattern, and wherein bottom and top surfaces of the gate insulation layer are substantially coplanar with bottom and top surfaces of the insulation layer pattern, respectively, and bottom and top surfaces of the gate electrode are substantially coplanar with bottom and top surfaces of the conductive layer pattern, respectively. The semiconductor memory further includes: a first contact plug coupled to the gate electrode and disposed over the gate electrode; and a second contact plug coupled to the conductive layer pattern and disposed over the conductive layer pattern. The first and second contact plugs include the same material, and wherein bottom and top surfaces of the first contact plug are substantially coplanar with bottom and top surfaces of the second contact plug, respectively.

The electronic device may further include a microprocessor which includes: a control unit configured to receive a signal including a command from an outside of the microprocessor, and performs extracting, decoding of the command, or controlling input or output of a signal of the microprocessor; an operation unit configured to perform an operation based on a result that the control unit decodes the command; and a memory unit configured to store data for performing the operation, data corresponding to a result of performing the operation, or an address of data for which the operation is performed, wherein the semiconductor memory is part of the memory unit in the microprocessor.

The electronic device may further include a processor which includes: a core unit configured to perform, based on a command inputted from an outside of the processor, an operation corresponding to the command, by using data; a cache memory unit configured to store data for performing the operation, data corresponding to a result of performing the operation, or an address of data for which the operation is performed; and a bus interface connected between the core unit and the cache memory unit, and configured to transmit data between the core unit and the cache memory unit, wherein the semiconductor memory is part of the cache memory unit in the processor.

The electronic device may further include a processing system which includes: a processor configured to decode a command received by the processor and control an operation for information based on a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between at least one of the processor, the auxiliary memory device and the main memory device and the outside, wherein the semiconductor memory is part of the auxiliary memory device or the main memory device in the processing system.

The electronic device may further include a data storage system which includes: a storage device configured to store data and conserve stored data regardless of power supply; a controller configured to control input and output of data to and from the storage device according to a command inputted form an outside; a temporary storage device configured to temporarily store data exchanged between the storage device and the outside; and an interface configured to perform communication between at least one of the storage device, the controller and the temporary storage device and the outside, wherein the semiconductor memory is part of the storage device or the temporary storage device in the data storage system.

The electronic device may further include a memory system which includes: a memory configured to store data and conserve stored data regardless of power supply; a memory controller configured to control input and output of data to and from the memory according to a command inputted form an outside; a buffer memory configured to buffer data exchanged between the memory and the outside; and an interface configured to perform communication between at least one of the memory, the memory controller and the buffer memory and the outside, wherein the semiconductor memory is part of the memory or the buffer memory in the memory system.

In another implementation, a method for fabricating an electronic device including a semiconductor memory may be provided. The method may include: providing a semiconductor substrate having a first region and a second region; forming an isolation trench and an initial capacitor trench in the first and second regions, respectively, by selectively etching the semiconductor substrate; forming an isolation layer and a sacrificial layer by filling the isolation trench and the initial capacitor trench, respectively, with an insulation material; removing the sacrificial layer using a mask pattern that covers the isolation layer in the first region and exposes the sacrificial layer in the second region, a portion of the semiconductor in the second region being exposed by removing the sacrificial layer; forming a capacitor trench by etching the exposed portion of the semiconductor substrate, the capacitor trench having a sidewall that forms a first angle with respect to a top surface of the semiconductor substrate, the isolation trench having a sidewall that forms a second angle with respect to the top surface of the semiconductor substrate, the first angle being more proximate to 90 degrees than the second angle; forming an insulation layer along the capacitor trench; and forming a conductive layer over the insulation layer.

Implementations of the above method may include one or more the following.

Forming the isolation trench and the initial capacitor trench includes performing a dry etch process on the semiconductor substrate, each of the isolation trench and the initial capacitor trench having a width that decreases as it approaches from a top surface to a bottom surface of a corresponding one of the isolation trench and the initial capacitor trench. Forming the capacitor trench includes performing a blanket etch process to etch a bottom portion of the exposed portion of the semiconductor substrate at a first etching rate and etch an upper portion of the exposed portion at a second etching rate, the first etching rate being higher than the second etching rate. Upper edges of the capacitor trench are more rounded than upper edges of the initial capacitor trench. A bottom surface of the capacitor trench is disposed lower than a bottom surface of the initial capacitor trench. The method further comprises: removing the mask pattern after forming the capacitor trench and before forming the insulation layer, wherein the insulation layer and the conductive layer are formed over a substantially entire surface of the semiconductor substrate in the first and second regions. The method further comprises: forming a gate pattern in the first region by selectively etching the conductive layer and the insulation layer in the first region after forming the insulation layer and the conductive layer. The method further comprises: forming a first contact plug and a second contact plug after forming the gate pattern, the first and second contact plugs being coupled to first and second portions of the conductive layer in the first region and second region, respectively. The forming of the isolation layer and the sacrificial layer includes performing a high aspect ratio process (HARP). Forming the insulation layer includes performing a thermal oxidation process.

These and other aspects, implementations and associated advantages are described in greater detail in the drawings, the description and the claims.

### BRIEF DESCRIPTION OF THE DRAWINGS

FIGS. 1 to 9 are cross-sectional views illustrating a semiconductor device and an example of a method for fabricating the semiconductor device in accordance with an implementation.

FIG. 10 is an example of configuration diagram of a microprocessor implementing memory circuitry based on the disclosed technology.

FIG. 11 is an example of configuration diagram of a processor implementing memory circuitry based on the disclosed technology.

FIG. 12 is an example of configuration diagram of a system implementing memory circuitry based on the disclosed technology.

FIG. 13 is an example of configuration diagram of a data storage system implementing memory circuitry based on the disclosed technology.

FIG. 14 is an example of configuration diagram of a memory system implementing memory circuitry based on the disclosed technology.

### DETAILED DESCRIPTION

The disclosed technology in this patent document can be implemented in various embodiments described below in more detail with reference to the accompanying drawings. The disclosed embodiments are examples only and may be in different forms and thus the disclosed technology should not be construed as limited to the embodiments set forth herein.

The drawings may not be necessarily to scale and in some instances, proportions of at least some of structures in the drawings may have been exaggerated in order to clearly illustrate certain features of the described examples or implementations. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure may not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

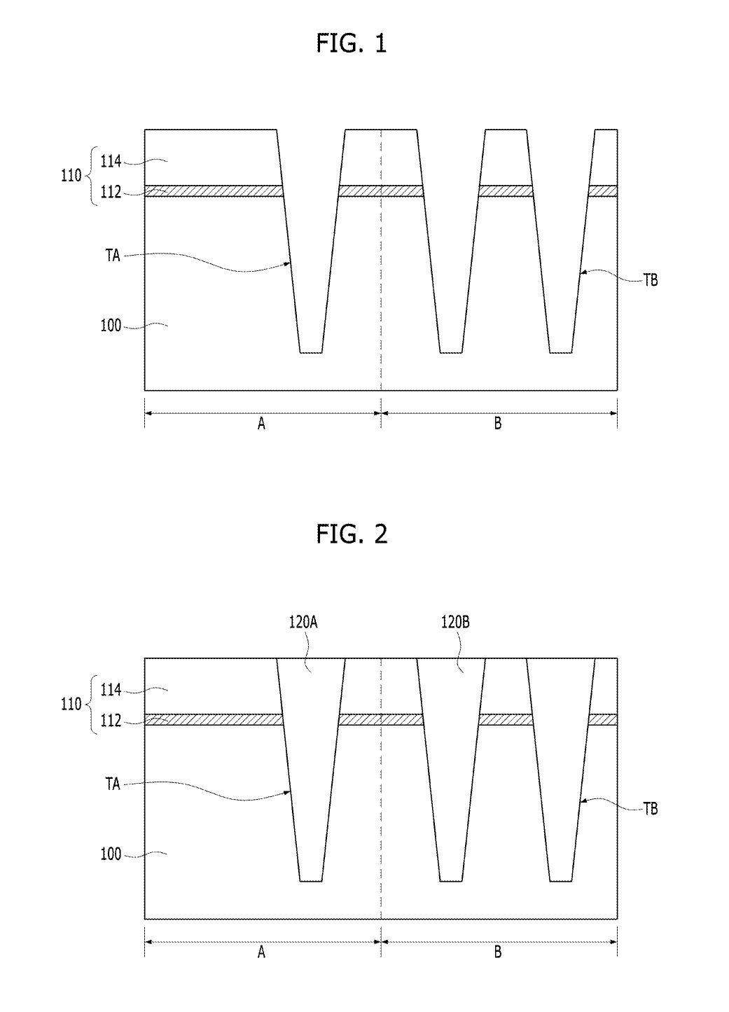

FIGS. 1 to 9 are cross-sectional views illustrating a semiconductor device and a method for fabricating the semiconductor device in accordance with an implementation.

Referring to FIG. 1, a semiconductor substrate 100 having a first region A and a second region B may be provided.

The semiconductor substrate 100 may include any one of various semiconductor materials such as silicon and further include a doped impurity. The second region B may be a region where a trench-type capacitor is formed, and the first region A may be a region where elements other than the capacitor, which include a transistor, are formed.

A first hard mask pattern 110 may be formed over the semiconductor substrate 100 so as to expose a portion of the first region A where an isolation trench TA is to be formed and a portion of the second region B where an initial capacitor trench TB is to be formed.

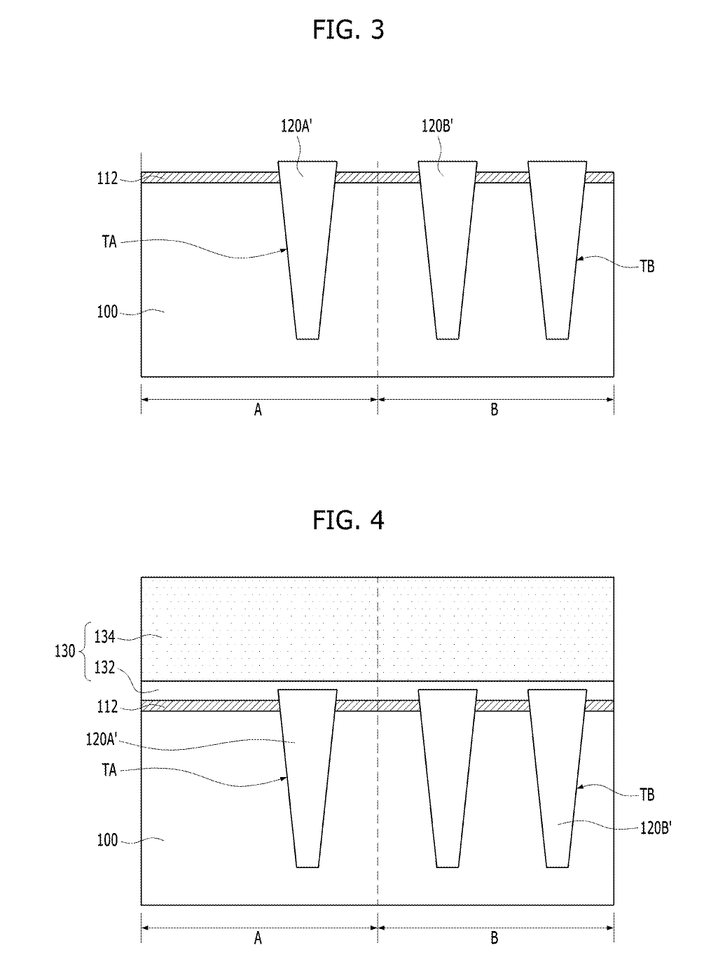

The first hard mask pattern 110 may have a single layer structure or a multi-layer structure. In an implementation, the first hard mask pattern 110 may have a double layer structure where two layer patterns 112 and 114 are stacked. The first lower layer pattern 112 may protect the semiconductor substrate 100 in subsequent processes, e.g., processes to be described with reference to FIGS. 3 to 5. The first lower layer pattern 112 may include an oxide such as a silicon oxide. The first upper layer pattern 114 may function as an etch barrier in an etch process of forming the trenches TA and TB in the first region A and the second region B, respectively. The first upper layer pattern 114 may include a nitride such as a silicon nitride.

The isolation trench TA and the initial capacitor trench TB may be formed in the first region A and the second region B, respectively, by etching corresponding portions of the semiconductor substrate 100 that are exposed by the first hard mask pattern 110. The initial capacitor trench TB may be formed in a region where a capacitor trench will be formed, and may be transformed, through a subsequent process, into the capacitor trench.

The semiconductor substrate 100 may be etched through a dry etch process, and hence the isolation trench TA and the initial capacitor trench TB may become narrower toward respective bottom portions. Specifically, each of the isolation trench TA and the initial capacitor trench TB may have a width that decreases as it approaches a corresponding bottom surface thereof. In other words, the isolation trench TA and the initial capacitor trench TB may have sidewalls each forming a preset angle that is not perpendicular to a top surface or a bottom surface of the semiconductor substrate 100. This is because an etch residue, e.g., a polymer, is generated and accumulated on etched sidewalls when the dry etch process is performed to form the isolation trench TA and initial capacitor trench TB.

Referring to FIG. 2, after an insulation material is formed over the structure resulting from the process of FIG. 1, a planarization process, for example, a chemical mechanical polishing (CMP) process, may be performed on the insulation material until a top surface of the first hard mask pattern 110 is exposed. Consequently, an isolation layer 120A filling the isolation trench TA and a sacrificial layer 120B filling the initial capacitor trench TB may be formed. The isolation layer 120A may define an active region of the semiconductor substrate 100 in the first region A. The sacrificial layer 120B may be removed in a subsequent process.

The insulation material for forming the isolation layer 120A and the sacrificial layer 120B may include an oxide such as a silicon oxide, a nitride such as a silicon nitride, or a combination thereof. The isolation layer 120A and the sacrificial layer 120B may be formed of an insulation material or using a process such that the insulation material substantially completely fills the isolation trench TA and the initial capacitor trench TB without a void. For example, the isolation layer 120A and the sacrificial layer 120B may include a material used in a high aspect ratio process (HARP). Particularly, since the isolation trench TA and the initial capacitor trench TB become narrower toward the bottom portions thereof, it may be easier to substantially completely fill the trenches TA and TB with the insulation material by substantially preventing voids from being generated in the trenches TA and TB.

Referring to FIG. 3, the first upper layer pattern 114 of the first hard mask pattern 110 may be removed. The first lower layer pattern 112 may remain to protect the semiconductor substrate 100 in the process of removing the first upper layer pattern 114 and a subsequent process.

The first upper layer pattern 114 may be removed through a wet etch process using chemicals having a high etch selectivity over the first lower layer pattern 112. In the wet etch process, since upper portions of the isolation layer 120A and sacrificial layer 120B are also removed, the surface height thereof may decrease. Therefore, as a result of the wet etch process, an isolation layer 120A′ and a sacrificial layer 120B′ having smaller heights than the isolation layer 120A and the sacrificial layer 120B are formed as shown in FIG. 3.

Referring to FIG. 4, a second hard mask layer 130 may be formed over the substrate structure resulting from the process of FIG. 3. The second hard mask layer 130 may have a single layer structure or a multi-layer structure. In an implementation, the second hard mask layer 130 may have a double layer structure where two layers 132 and 134 are stacked. The second upper layer 134 may include a carbon-containing material. The second lower layer 132 may be interposed between the second upper layer 134 and one or more layers, which include the isolation layer 120A′, the sacrificial layer 120B′, the first lower layer pattern 112, and the semiconductor substrate 100. The second upper layer 134 may function as a buffer layer. The second lower layer 132 may include a nitride such as a silicon nitride.

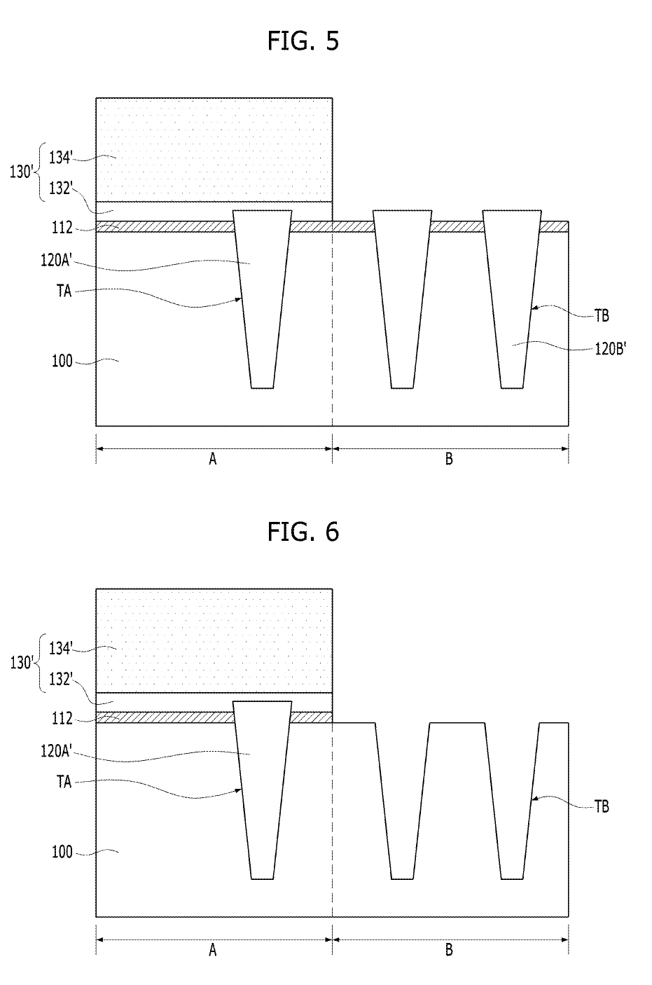

Referring to FIG. 5, the second hard mask layer 130 may be patterned through a mask process and an etch process.

Consequently, a second hard mask pattern 130′ may be formed to cover the first region A and to expose the second region B. The second hard mask pattern 130′ may have a stacked structure of a second lower layer pattern 132′ and a second upper layer pattern 134′ that remain in the first region A. The sacrificial layer 120B′ and a portion of the first lower layer pattern 112 in the second region B may be exposed by the mask process and the etch process.

Referring to FIG. 6, the exposed sacrificial layer 120B′ and the exposed portion of the first lower layer pattern 112 may be removed through a wet etch process.

When the sacrificial layer 120B′ and the first lower layer pattern 112 are formed of the same material, for example, a silicon nitride, the sacrificial layer 120B′ and the first lower layer pattern 112 may be removed together using the same etch process. When the first lower layer pattern 112 is formed of a different material from the sacrificial layer 120B′, the first lower layer pattern 112 and the sacrificial layer 120B′ may be removed using different etch processes.

As a result of the above wet etch process, the initial capacitor trench TB, which has been formed as shown in FIG. 1, may be exposed again in the second region B.

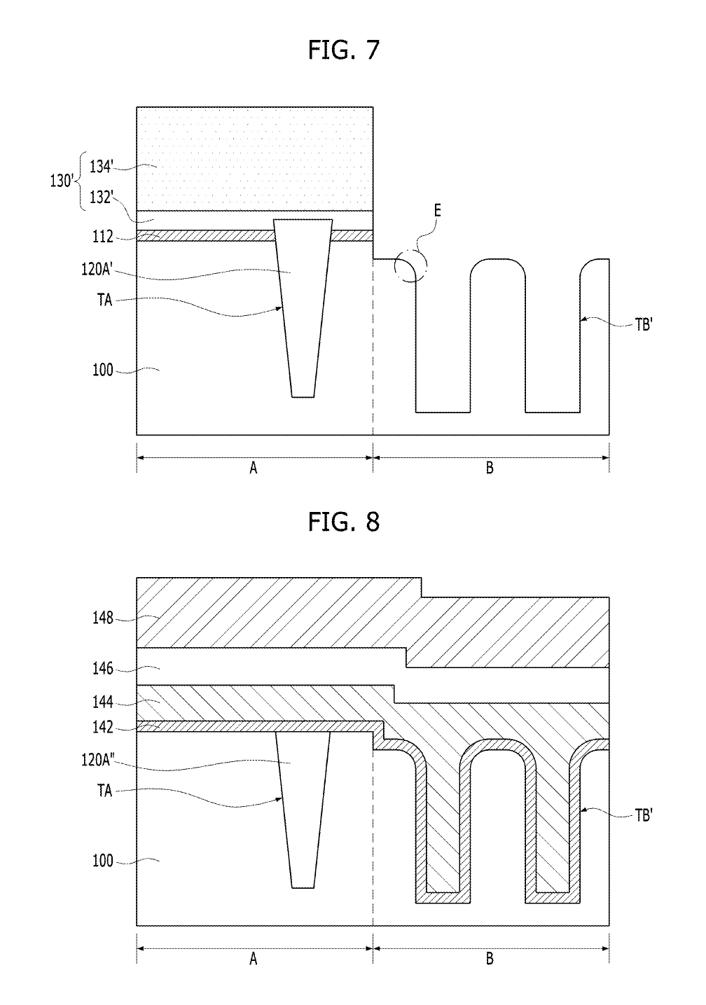

Referring to FIG. 7, an additional etch process is performed on a portion of the semiconductor substrate 100 that is in the second region B, and thus the initial capacitor trench TB is transformed into a capacitor trench TB′.

The additional etch process may be a blanket etch process, hence an etching amount thereof may increase toward a bottom portion of the initial capacitor trench TB. For example, when the additional etch process is performed on the portion of the semiconductor substrate 100, an etching rate for the bottom portion of the initial capacitor trench TB is higher than an etching rate for an upper portion of the initial capacitor trench TB. In other words, as a result of the additional etch process, while a width of an upper surface of the capacitor trench TB′ may slightly increase from a width of the upper surface of the initial capacitor trench TB and/or the isolation trench TA, a width of the bottom surface of the capacitor trench TB′ may greatly increase from a width of the bottom surface of the initial capacitor trench TB and/or the isolation trench TA. That is, after the additional etch process is performed, a difference between the width of the upper surface of the capacitor trench TB′ and the width of the upper surface of the initial capacitor trench TB is smaller than a difference between the width of the bottom surface of the capacitor trench TB′ and the width of the bottom surface of the initial capacitor trench TB. Consequently, sidewalls of the capacitor trench TB′ may be substantially perpendicular to the top or bottom surface of the semiconductor substrate 100 while the initial capacitor trench TB and/or the isolation trench TA have the preset angle. In other words, the capacitor trench TB′ may have substantially vertical sidewalls.

Through the additional etch process, the bottom surface of the capacitor trench TB′ may become lower than the bottom surfaces of the initial capacitor trench TB and/or the isolation trench TA.

Through the additional etch process, the capacitor trench TB′ may have more rounded upper edges (for example, as indicated by a dashed circle “E” in FIG. 7) than the initial capacitor trench TB and/or the isolation trench TA. For example, the upper edge of the capacitor trench TB′ has a curved portion greater than that of a corresponding upper edge of the initial capacitor trench TB.

In the additional etch process, since the first region A is covered by the second hard mask pattern 130′, a shape of the isolation trench TA in the first region A may remain unchanged.

Referring to FIG. 8, the second hard mask pattern 130′ and the first lower layer pattern 112 in the first region A may be removed. In the removal process, an upper portion of the isolation layer 120A′ is also removed, and thus an isolation layer 120A″ is formed. An upper surface of the isolation layer 120A″ may be disposed substantially coplanar with an upper surface of the semiconductor substrate 100.

Subsequently, an insulation layer 142 may be formed along a surface profile of the structure resulting from the removal process, and a first conductive layer 144 having a thickness enough to fill the capacitor trench TB′ in the second region B may be formed over the insulation layer 142.

Subsequently, a second conductive layer 146 may be formed over the first conductive layer 144, and a third hard mask layer 148 may be formed over the second conductive layer 146. The insulation layer 142 may be formed by depositing an insulation material or by thermally oxidizing a portion of the semiconductor substrate 100. The first conductive layer 144, the second conductive layer 146, and the third hard mask layer 148 may be formed through a deposition process.

In the second region B, the semiconductor substrate 100 may function as a lower electrode of a capacitor, the first and second conductive layers 144 and 146 may function as an upper electrode of the capacitor, and the insulation layer 142 may function as a dielectric of the capacitor between the semiconductor substrate 100 and the first and second conductive layers 144 and 146. When a transistor is formed in the first region A, the semiconductor substrate 100 may include a channel and a junction region of the transistor, the insulation layer 142 may function as a gate insulation layer, and the first and second conductive layers 144 and 146 may function as a gate electrode. The third hard mask layer 148 may function as an etch barrier for etching the first and second conductive layers 144 and 146 and the insulation layer 142 in the first region A and the second region B.

The insulation layer 142 may include an oxide such as a silicon oxide, the first conductive layer 144 may include a semiconductor material, e.g., a polysilicon, doped with an impurity, and the second conductive layer 146 may include a metal material such as tungsten. The third hard mask layer 148 may include a nitride such as a silicon nitride.

In the implementation shown in FIG. 8, although a double layer structure of the first and second conductive layers 144 and 146 is used as the gate electrode in the first region A and used as the upper electrode of the capacitor in the second region B, implementations are not limited thereto. In another implementation, a single layer structure or a multi-layer structure where three or more layers are stacked may be used as the gate electrode in the first region A and used as the upper electrode of the capacitor in the second region B.

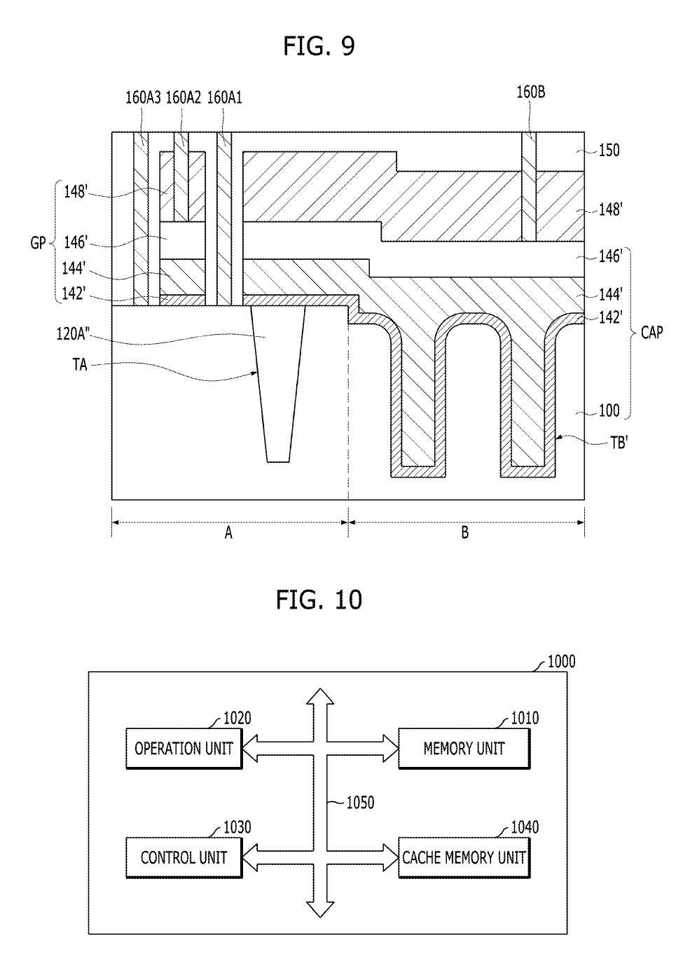

Referring to FIG. 9, a third hard mask pattern 148′, a second conductive layer pattern 146′, a first conductive layer pattern 144′, and an insulation layer pattern 142′ may be formed by selectively etching the third hard mask layer 148, the second conductive layer 146, the first conductive layer 144, and the insulation layer 142 in the first region A. Hence, a gate pattern GP including a first portion of the insulation layer pattern 142′, a first portion of the first conductive layer pattern 144′, a first portion of the second conductive layer pattern 146′, and a first portion of the third hard mask pattern 148′ may be formed in the first region A. In the first region A, the first portions of the insulation layer pattern 142′, the first conductive layer pattern 144′, the second conductive layer pattern 146′, and the third hard mask pattern 148′ are spaced apart from second portions of the patterns 142′, 144′, 146′ and 148′. Specifically, the first portion of the insulation layer pattern 142′ functions as a gate insulation layer of the gate pattern GP. The first portions of the first conductive layer pattern 144′ and the second conductive layer pattern 146′ function as a gate electrode of the gate pattern GP. In addition, a capacitor CAP, which includes the semiconductor substrate 100 having the capacitor trench TB′, a third portion of the insulation layer pattern 142′ formed along a surface profile of the semiconductor substrate 100 having the capacitor trench TB′, a third portion of the first conductive layer pattern 144′ filling the capacitor trench TB′ over the third portion of the insulation layer pattern 142′, and a third portion of the second conductive layer pattern 146′ over the third portion of the first conductive pattern 144′, may be formed in the second region B. The third portions of the insulation layer pattern 142′, the first conductive layer pattern 144′, and the second conductive layer pattern 146′ in the second region B are adjacent to the second portions of the patterns 142′, 144′, and 146′ in the first region A, respectively. Specifically, the semiconductor substrate 100 functions as a lower electrode of the capacitor CAP, and the third portion of the insulation layer pattern 142′ functions as a dielectric of the capacitor CAP. The third portions of the first conductive layer pattern 144′ and the second conductive layer pattern 146′ function as an upper electrode of the capacitor CAP.

After the gate pattern GP is formed in the first region A, one or more junction regions (not shown) may be formed by implanting impurities into one or more portions of the semiconductor substrate 100 exposed by the gate pattern GP. In an implementation, two junction regions (not shown) are formed by implanting impurities into two portions of the semiconductor substrate that are adjacent to a bottom surface of the first portion of the insulation layer pattern 142′ in the gate pattern GP. In other words, the two portions of the semiconductor substrate are disposed at two opposite sides of the gate pattern GP. In this implementation, these junction regions and the gate pattern GP form a transistor.

Subsequently, an inter-layer dielectric layer 150 may be formed to cover the structure including the gate pattern GP and the capacitor CAP. The inter-layer dielectric layer 150 may include any one of various insulation materials such as a silicon oxide, a silicon nitride, and a combination thereof.

First and third contact plugs 160A1 and 160A3 may be formed to be coupled to the junction regions formed in the two portions of the semiconductor substrate 100 at the two opposite sides of the gate pattern GP, respectively. The first and third contact plugs 160A1 and 160A3 pass through corresponding portions of the inter-layer dielectric layer 150, respectively, in the first region A. A second contact plug 160A2 may be formed to be coupled to the second conductive layer pattern 146′. The second contact plug 160A2 passes through a corresponding portion of the inter-layer dielectric layer 150 and the first portion of the third hard mask pattern 148′ in the first region A. A fourth contact plug 160B may be formed to be coupled to the third portion of the second conductive layer pattern 146′ in the second region B. The fourth contact plug 160B passes through a corresponding portion of the inter-layer dielectric layer 150 and the third portion of the third hard mask pattern 148′ in the second region B.

The first and third contact plugs 160A1 and 160A3 may be electrically coupled to a source and a drain of the transistor that correspond to the junction regions formed in the first region A, and may supply a voltage or a current to the source and the drain of the transistor. The second contact plug 160A2 may be electrically coupled to a gate electrode of the transistor that corresponds to the first portions of the first conductive layer pattern 144′ and the second conductive layer pattern 146′, and may supply a voltage or a current to the gate electrode of the transistor. The fourth contact plug 160B may be electrically coupled to the upper electrode of the capacitor CAP that corresponds to the third portions of the first conductive layer pattern 144′ and the second conductive layer pattern 146′, and may supply a voltage or a current to the upper electrode of the capacitor CAP.

The second and fourth contact plugs 160A2 and 160B may be formed by selectively etching the inter-layer dielectric layer 150 and the third hard mask pattern 148′ to form contact holes in the first and second regions A and B, respectively, and then by filling the contact holes with a conductive material such as a metal. The second and fourth contact plugs 160A2 and 160B may be formed simultaneously using the same mask and the same etch process. Particularly, when the inter-layer dielectric layer 150 and the third hard mask pattern 148′ are selectively etched, the second contact plug 160A2 and the fourth contact plug 160B may be formed using the same mask and the same etch process.

The first and third contact plugs 160A1 and 160A3 may be formed by selectively etching the inter-layer dielectric layer 150 in the first region A to thereby form contact holes at the two opposite sides of the gate pattern GP, and then by filling the contact holes with a conductive material such as a metal. The first and third contact plugs 160A1 and 160A3 may be formed simultaneously using the same mask and the same etch process.

The semiconductor device as shown in FIG. 9 may be fabricated through the aforementioned fabrication processes.

Referring back to FIG. 9, the semiconductor device according to an implementation may include the semiconductor substrate 100 including the isolation trench TA in the first region A and the capacitor trench TB′ in the second region B. The semiconductor device may further include the isolation layer 120A″ filling the isolation trench TA, the insulation layer pattern 142′ disposed along a surface profile of the semiconductor substrate 100 including the isolation layer 120A″ and the capacitor trench TB′, the first conductive layer pattern 144′ disposed over the insulation layer pattern 142′ and having a thickness enough to fill the capacitor trench TB′ in the second region B, the second conductive layer pattern 146′ over the first conductive pattern 144′, and the third hard mask pattern 148′ over the second conductive layer pattern 146′.

The isolation trench TA may have more sloping sidewalls than the capacitor trench TB′. Specifically, the isolation trench TA has a sidewall forming a non-perpendicular angle with respect to the top surface of the semiconductor substrate 10 in the first region A, and the capacitor trench TB′ has a sidewall substantially perpendicular to the bottom surface of the capacitor trench TB′. For example, the sidewall of the capacitor trench TB′ forms a first angle with respect to the top surface of the semiconductor substrate 10 in the second region B, and the sidewall of the isolation trench TA forms a second angle with respect to the top surface of the semiconductor substrate 10 in the first region A. The first angle is more proximate to 90 degrees than the second angle. The gate pattern GP includes the first portions of the insulation layer pattern 142′, the first conductive layer pattern 144′, the second conductive layer pattern 146′, and the third hard mask pattern 148′ in the first region A. The capacitor CAP includes the semiconductor substrate 100 and the third portions of the insulation layer pattern 142′, the first conductive pattern 144′, and the second conductive layer pattern 146′ in the second region B.

The semiconductor device and the fabrication method thereof as described above in accordance with an implementation may have the following beneficial aspects.

First, because shapes of the isolation trench TA and the capacitor trench TB′ are different from each other, desirable characteristics of the isolation trench TA and the capacitor trench TB′ may be satisfied.

Specifically, when the isolation trench TA becomes narrower toward the bottom surface thereof, it may be easier to fill the isolation trench TA with an insulation material compared with when the isolation trench TA has vertical sidewalls. If the isolation trench TA had the vertical sidewalls, because the isolation trench TA may not be completely filled with the insulation material, a void would occur in the isolation layer 120A and thus characteristics of the semiconductor device would deteriorate. However, according to the implementation of this patent document, the occurrence of the void may be substantially prevented.

In addition, because the capacitor trench TB′ has substantially vertical sidewalls, differently from the isolation trench TA, various characteristics of the capacitor CAP may be improved. In particular, the third portion of the insulation layer pattern 142′ that functions as a capacitor dielectric in the second region B may be relatively thick and have a substantially uniform thickness. When the capacitor trench TB′ has sloping sidewalls such that the width of the capacitor trench TB′ decreases as it approaches the bottom surface thereof, and the insulation layer 142 is formed by oxidizing the semiconductor substrate 100, growth characteristics of an oxidation layer generated by a thermal oxidation process may deteriorate, and a thickness of the oxidation layer may vary widely. However, according to an implementation of this patent document, because the capacitor trench TB′ has substantially vertical sidewalls, the oxidation layer may be formed to have a substantially uniform thickness and be thick. When the capacitor dielectric is thick and has the substantially uniform thickness, a breakdown voltage of the capacitor may increase, and a leakage current through the capacitor may decrease. As the breakdown voltage of the capacitor increases, an area required to form the capacitor may be reduced, and thus an occupying area of the semiconductor device may be also reduced. Furthermore, the layer quality of the insulation layer pattern 142′ that functions as the capacitor dielectric in the second region B may be improved. If the capacitor trench TB′ had the sloping sidewalls and the additional etch process were not performed, polymer residues deposited on the sidewalls during the previous etch process would remain, and thus the layer quality of the insulation layer pattern 142′ would deteriorate. However, according to an implementation of this patent document, because the deposited polymers are removed by the additional etch process, it is possible to further improve the layer quality of the insulation layer pattern 142′.

Moreover, since the capacitor trench TB′ having the vertical sidewalls may be obtained by performing the additional etch process on the initial capacitor trench TB, such a fabrication process may improve characteristics of the capacitor.

Moreover, since the upper edges of the capacitor trench TB′ become rounded by performing the additional etch process on the initial capacitor trench TB, issues caused by an electric field concentrated on sharp edges, for example, hump characteristic deterioration, may be addressed.

As is apparent from the above descriptions, in the semiconductor device and the method for fabricating the same in accordance with the implementation, desirable characteristics for an isolation layer and desirable characteristics for a trench-type capacitor may be satisfied.

The above and other memory circuits or semiconductor devices based on the disclosed technology can be used in a range of devices or systems. FIGS. 10-14 provide some examples of devices or systems that can implement the memory circuits disclosed herein.

FIG. 10 is an example of configuration diagram of a microprocessor implementing memory circuitry based on the disclosed technology.

Referring to FIG. 10, a microprocessor 1000 may perform tasks for controlling and tuning a series of processes of receiving data from various external devices, processing the data, and outputting processing results to external devices. The microprocessor 1000 may include a memory unit 1010, an operation unit 1020, a control unit 1030, and so on. The microprocessor 1000 may be various data processing units such as a central processing unit (CPU), a graphic processing unit (GPU), a digital signal processor (DSP) and an application processor (AP).

The memory unit 1010 is a part which stores data in the microprocessor 1000, as a processor register, register or the like. The memory unit 1010 may include a data register, an address register, a floating point register and so on. Besides, the memory unit 1010 may include various registers. The memory unit 1010 may perform the function of temporarily storing data for which operations are to be performed by the operation unit 1020, result data of performing the operations and addresses where data for performing of the operations are stored.

The memory unit 1010 may include one or more of the above-described semiconductor devices in accordance with the implementations. For example, the memory unit 1010 may include a semiconductor substrate having an isolation trench in a first region and a capacitor trench in a second region; an isolation layer filling the isolation trench; an insulation layer pattern disposed along the capacitor trench; and a conductive layer pattern filling the capacitor trench over the insulation layer pattern, wherein a capacitor includes a first portion of the semiconductor substrate in the second region, the insulation layer pattern, and the conductive pattern, and wherein a sidewall of the capacitor trench has a first angle with respect to a surface of the semiconductor substrate and a sidewall of the isolation trench has a second angle with respect to the surface of the semiconductor substrate, the first angle being more proximate to 90 degrees than the second angle. Through this, both an isolation layer characteristic and a capacitor characteristic of the memory unit 1010 may be satisfied. As a consequence, operating characteristics of the microprocessor 1000 may be improved.

The operation unit 1020 may perform four arithmetical operations or logical operations according to results that the control unit 1030 decodes commands. The operation unit 1020 may include at least one arithmetic logic unit (ALU) and so on.

The control unit 1030 may receive signals from the memory unit 1010, the operation unit 1020 and an external device of the microprocessor 1000, perform extraction, decoding of commands, and controlling input and output of signals of the microprocessor 1000, and execute processing represented by programs.

The microprocessor 1000 according to the present implementation may additionally include a cache memory unit 1040 which can temporarily store data to be inputted from an external device other than the memory unit 1010 or to be outputted to an external device. In this case, the cache memory unit 1040 may exchange data with the memory unit 1010, the operation unit 1020 and the control unit 1030 through a bus interface 1050.

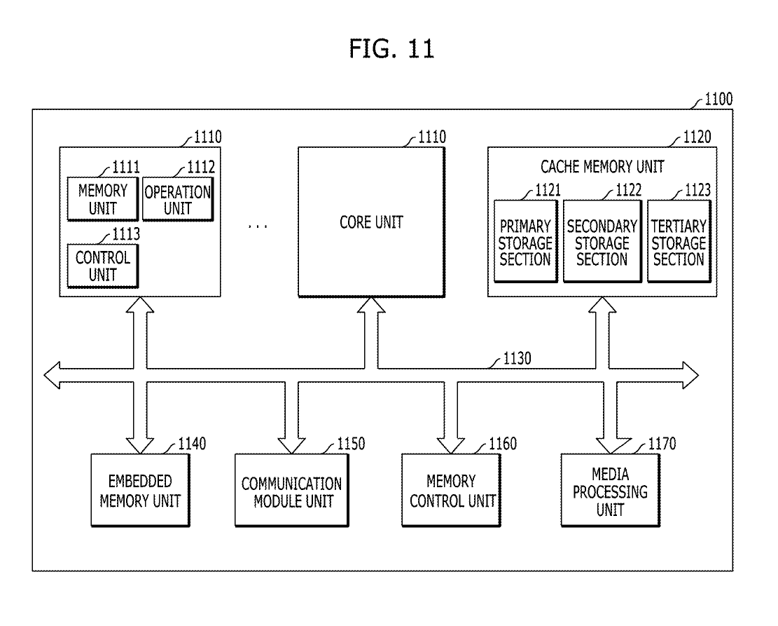

FIG. 11 is an example of configuration diagram of a processor implementing memory circuitry based on the disclosed technology.

Referring to FIG. 11, a processor 1100 may improve performance and realize multi-functionality by including various functions other than those of a microprocessor which performs tasks for controlling and tuning a series of processes of receiving data from various external devices, processing the data, and outputting processing results to external devices. The processor 1100 may include a core unit 1110 which serves as the microprocessor, a cache memory unit 1120 which serves to storing data temporarily, and a bus interface 1130 for transferring data between internal and external devices. The processor 1100 may include various system-on-chips (SoCs) such as a multi-core processor, a graphic processing unit (GPU) and an application processor (AP).

The core unit 1110 of the present implementation is a part which performs arithmetic logic operations for data inputted from an external device, and may include a memory unit 1111, an operation unit 1112 and a control unit 1113.

The memory unit 1111 is a part which stores data in the processor 1100, as a processor register, a register or the like. The memory unit 1111 may include a data register, an address register, a floating point register and so on. Besides, the memory unit 1111 may include various registers. The memory unit 1111 may perform the function of temporarily storing data for which operations are to be performed by the operation unit 1112, result data of performing the operations and addresses where data for performing of the operations are stored. The operation unit 1112 is a part which performs operations in the processor 1100. The operation unit 1112 may perform four arithmetical operations, logical operations, according to results that the control unit 1113 decodes commands, or the like. The operation unit 1112 may include at least one arithmetic logic unit (ALU) and so on. The control unit 1113 may receive signals from the memory unit 1111, the operation unit 1112 and an external device of the processor 1100, perform extraction, decoding of commands, controlling input and output of signals of processor 1100, and execute processing represented by programs.

The cache memory unit 1120 is a part which temporarily stores data to compensate for a difference in data processing speed between the core unit 1110 operating at a high speed and an external device operating at a low speed. The cache memory unit 1120 may include a primary storage section 1121, a secondary storage section 1122 and a tertiary storage section 1123. In general, the cache memory unit 1120 includes the primary and secondary storage sections 1121 and 1122, and may include the tertiary storage section 1123 in the case where high storage capacity is required. As the occasion demands, the cache memory unit 1120 may include an increased number of storage sections. That is to say, the number of storage sections which are included in the cache memory unit 1120 may be changed according to a design. The speeds at which the primary, secondary and tertiary storage sections 1121, 1122 and 1123 store and discriminate data may be the same or different. In the case where the speeds of the respective storage sections 1121, 1122 and 1123 are different, the speed of the primary storage section 1121 may be largest. At least one storage section of the primary storage section 1121, the secondary storage section 1122 and the tertiary storage section 1123 of the cache memory unit 1120 may include one or more of the above-described semiconductor devices in accordance with the implementations. For example, the cache memory unit 1120 may include a semiconductor substrate having an isolation trench in a first region and a capacitor trench in a second region; an isolation layer filling the isolation trench; an insulation layer pattern disposed along the capacitor trench; and a conductive layer pattern filling the capacitor trench over the insulation layer pattern, wherein a capacitor includes a first portion of the semiconductor substrate in the second region, the insulation layer pattern, and the conductive pattern, and wherein a sidewall of the capacitor trench has a first angle with respect to a surface of the semiconductor substrate and a sidewall of the isolation trench has a second angle with respect to the surface of the semiconductor substrate, the first angle being more proximate to 90 degrees than the second angle. Through this, both an isolation layer characteristic and a capacitor characteristic of the cache memory unit 1120 may be satisfied. As a consequence, operating characteristics of the processor 1100 may be improved.

Although it was shown in FIG. 11 that all the primary, secondary and tertiary storage sections 1121, 1122 and 1123 are configured inside the cache memory unit 1120, it is to be noted that all the primary, secondary and tertiary storage sections 1121, 1122 and 1123 of the cache memory unit 1120 may be configured outside the core unit 1110 and may compensate for a difference in data processing speed between the core unit 1110 and the external device. Meanwhile, it is to be noted that the primary storage section 1121 of the cache memory unit 1120 may be disposed inside the core unit 1110 and the secondary storage section 1122 and the tertiary storage section 1123 may be configured outside the core unit 1110 to strengthen the function of compensating for a difference in data processing speed. In another implementation, the primary and secondary storage sections 1121, 1122 may be disposed inside the core units 1110 and tertiary storage sections 1123 may be disposed outside core units 1110.

The bus interface 1130 is a part which connects the core unit 1110, the cache memory unit 1120 and external device and allows data to be efficiently transmitted.

The processor 1100 according to the present implementation may include a plurality of core units 1110, and the plurality of core units 1110 may share the cache memory unit 1120. The plurality of core units 1110 and the cache memory unit 1120 may be directly connected or be connected through the bus interface 1130. The plurality of core units 1110 may be configured in the same way as the above-described configuration of the core unit 1110. In the case where the processor 1100 includes the plurality of core unit 1110, the primary storage section 1121 of the cache memory unit 1120 may be configured in each core unit 1110 in correspondence to the number of the plurality of core units 1110, and the secondary storage section 1122 and the tertiary storage section 1123 may be configured outside the plurality of core units 1110 in such a way as to be shared through the bus interface 1130. The processing speed of the primary storage section 1121 may be larger than the processing speeds of the secondary and tertiary storage section 1122 and 1123. In another implementation, the primary storage section 1121 and the secondary storage section 1122 may be configured in each core unit 1110 in correspondence to the number of the plurality of core units 1110, and the tertiary storage section 1123 may be configured outside the plurality of core units 1110 in such a way as to be shared through the bus interface 1130.

The processor 1100 according to the present implementation may further include an embedded memory unit 1140 which stores data, a communication module unit 1150 which can transmit and receive data to and from an external device in a wired or wireless manner, a memory control unit 1160 which drives an external memory device, and a media processing unit 1170 which processes the data processed in the processor 1100 or the data inputted from an external input device and outputs the processed data to an external interface device and so on. Besides, the processor 1100 may include a plurality of various modules and devices. In this case, the plurality of modules which are added may exchange data with the core units 1110 and the cache memory unit 1120 and with one another, through the bus interface 1130.

The embedded memory unit 1140 may include not only a volatile memory but also a nonvolatile memory. The volatile memory may include a DRAM (dynamic random access memory), a mobile DRAM, an SRAM (static random access memory), and a memory with similar functions to above mentioned memories, and so on. The nonvolatile memory may include a ROM (read only memory), a NOR flash memory, a NAND flash memory, a phase change random access memory (PRAM), a resistive random access memory (RRAM), a spin transfer torque random access memory (STTRAM), a magnetic random access memory (MRAM), a memory with similar functions.

The communication module unit 1150 may include a module capable of being connected with a wired network, a module capable of being connected with a wireless network and both of them. The wired network module may include a local area network (LAN), a universal serial bus (USB), an Ethernet, power line communication (PLC) such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB) such as various devices which send and receive data without transmit lines, and so on.

The memory control unit 1160 is to administrate and process data transmitted between the processor 1100 and an external storage device operating according to a different communication standard. The memory control unit 1160 may include various memory controllers, for example, devices which may control IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The media processing unit 1170 may process the data processed in the processor 1100 or the data inputted in the forms of image, voice and others from the external input device and output the data to the external interface device. The media processing unit 1170 may include a graphic processing unit (GPU), a digital signal processor (DSP), a high definition audio device (HD audio), a high definition multimedia interface (HDMI) controller, and so on.

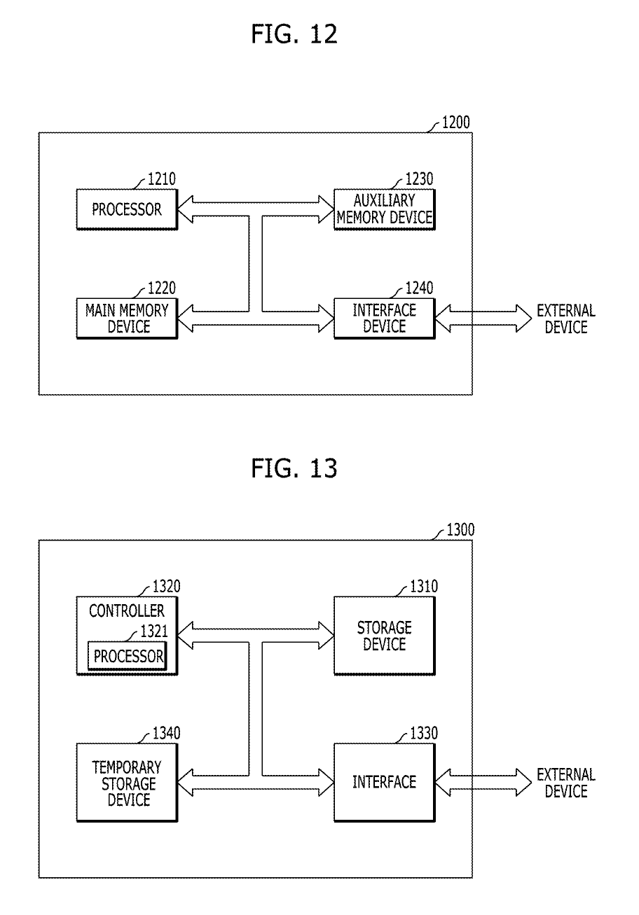

FIG. 12 is an example of configuration diagram of a system implementing memory circuitry based on the disclosed technology.

Referring to FIG. 12, a system 1200 as an apparatus for processing data may perform input, processing, output, communication, storage, etc. to conduct a series of manipulations for data. The system 1200 may include a processor 1210, a main memory device 1220, an auxiliary memory device 1230, an interface device 1240, and so on. The system 1200 of the present implementation may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 may decode inputted commands and processes operation, comparison, etc. for the data stored in the system 1200, and controls these operations. The processor 1210 may include a microprocessor unit (MPU), a central processing unit (CPU), a single/multi-core processor, a graphic processing unit (GPU), an application processor (AP), a digital signal processor (DSP), and so on.

The main memory device 1220 is a storage which can temporarily store, call and execute program codes or data from the auxiliary memory device 1230 when programs are executed and can conserve memorized contents even when power supply is cut off. The main memory device 1220 may include one or more of the above-described semiconductor devices in accordance with the implementations. For example, the main memory device 1220 may include a semiconductor substrate having an isolation trench in a first region and a capacitor trench in a second region; an isolation layer filling the isolation trench; an insulation layer pattern disposed along the capacitor trench; and a conductive layer pattern filling the capacitor trench over the insulation layer pattern, wherein a capacitor includes a first portion of the semiconductor substrate in the second region, the insulation layer pattern, and the conductive pattern, and wherein a sidewall of the capacitor trench has a first angle with respect to a surface of the semiconductor substrate and a sidewall of the isolation trench has a second angle with respect to the surface of the semiconductor substrate, the first angle being more proximate to 90 degrees than the second angle. Through this, both an isolation characteristic and a capacitor characteristic of the main memory device 1220 may be satisfied. As a consequence, operating characteristics of the system 1200 may be improved.

Also, the main memory device 1220 may further include a static random access memory (SRAM), a dynamic random access memory (DRAM), and so on, of a volatile memory type in which all contents are erased when power supply is cut off. Unlike this, the main memory device 1220 may not include the semiconductor devices according to the implementations, but may include a static random access memory (SRAM), a dynamic random access memory (DRAM), and so on, of a volatile memory type in which all contents are erased when power supply is cut off.

The auxiliary memory device 1230 is a memory device for storing program codes or data. While the speed of the auxiliary memory device 1230 is slower than the main memory device 1220, the auxiliary memory device 1230 can store a larger amount of data. The auxiliary memory device 1230 may include one or more of the above-described semiconductor devices in accordance with the implementations. For example, the auxiliary memory device 1230 may include a semiconductor substrate having an isolation trench in a first region and a capacitor trench in a second region; an isolation layer filling the isolation trench; an insulation layer pattern disposed along the capacitor trench; and a conductive layer pattern filling the capacitor trench over the insulation layer pattern, wherein a capacitor includes a first portion of the semiconductor substrate in the second region, the insulation layer pattern, and the conductive pattern, and wherein a sidewall of the capacitor trench has a first angle with respect to a surface of the semiconductor substrate and a sidewall of the isolation trench has a second angle with respect to the surface of the semiconductor substrate, the first angle being more proximate to 90 degrees than the second angle. Through this, both an isolation characteristic and a capacitor characteristic of the auxiliary memory device 1230 may be satisfied. As a consequence, operating characteristics of the system 1200 may be improved.

Also, the auxiliary memory device 1230 may further include a data storage system (see the reference numeral 1300 of FIG. 13) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. Unlike this, the auxiliary memory device 1230 may not include the semiconductor devices according to the implementations, but may include data storage systems (see the reference numeral 1300 of FIG. 10) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The interface device 1240 may be to perform exchange of commands and data between the system 1200 of the present implementation and an external device. The interface device 1240 may be a keypad, a keyboard, a mouse, a speaker, a mike, a display, various human interface devices (HIDs), a communication device, and so on. The communication device may include a module capable of being connected with a wired network, a module capable of being connected with a wireless network and both of them. The wired network module may include a local area network (LAN), a universal serial bus (USB), an Ethernet, power line communication (PLC), such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

FIG. 13 is an example of configuration diagram of a data storage system implementing memory circuitry based on the disclosed technology.

Referring to FIG. 13, a data storage system 1300 may include a storage device 1310 which has a nonvolatile characteristic as a component for storing data, a controller 1320 which controls the storage device 1310, an interface 1330 for connection with an external device, and a temporary storage device 1340 for storing data temporarily. The data storage system 1300 may be a disk type such as a hard disk drive (HDD), a compact disc read only memory (CDROM), a digital versatile disc (DVD), a solid state disk (SSD), and so on, and a card type such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The storage device 1310 may include a nonvolatile memory which stores data semi-permanently. The nonvolatile memory may include a ROM (read only memory), a NOR flash memory, a NAND flash memory, a phase change random access memory (PRAM), a resistive random access memory (RRAM), a magnetic random access memory (MRAM), and so on.

The controller 1320 may control exchange of data between the storage device 1310 and the interface 1330. To this end, the controller 1320 may include a processor 1321 for performing an operation for, processing commands inputted through the interface 1330 from an outside of the data storage system 1300 and so on.

The interface 1330 is to perform exchange of commands and data between the data storage system 1300 and the external device. In the case where the data storage system 1300 is a card type, the interface 1330 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. In the case where the data storage system 1300 is a disk type, the interface 1330 may be compatible with interfaces, such as IDE (Integrated Device Electronics), SATA (Serial Advanced Technology Attachment), SCSI (Small Computer System Interface), eSATA (External SATA), PCMCIA (Personal Computer Memory Card International Association), a USB (universal serial bus), and so on, or be compatible with the interfaces which are similar to the above mentioned interfaces. The interface 1330 may be compatible with one or more interfaces having a different type from each other.

The temporary storage device 1340 can store data temporarily for efficiently transferring data between the interface 1330 and the storage device 1310 according to diversifications and high performance of an interface with an external device, a controller and a system. The temporary storage device 1340 for temporarily storing data may include one or more of the above-described semiconductor devices in accordance with the implementations. The temporary storage device 1340 may include a semiconductor substrate having an isolation trench in a first region and a capacitor trench in a second region; an isolation layer filling the isolation trench; an insulation layer pattern disposed along the capacitor trench; and a conductive layer pattern filling the capacitor trench over the insulation layer pattern, wherein a capacitor includes a first portion of the semiconductor substrate in the second region, the insulation layer pattern, and the conductive pattern, and wherein a sidewall of the capacitor trench has a first angle with respect to a surface of the semiconductor substrate and a sidewall of the isolation trench has a second angle with respect to the surface of the semiconductor substrate, the first angle being more proximate to 90 degrees than the second angle. Through this, both an isolation layer characteristic and a capacitor characteristic of the temporary storage device 1340 may be satisfied. As a consequence, operating characteristics and data storage characteristics of the data storage system 1300 may be improved.

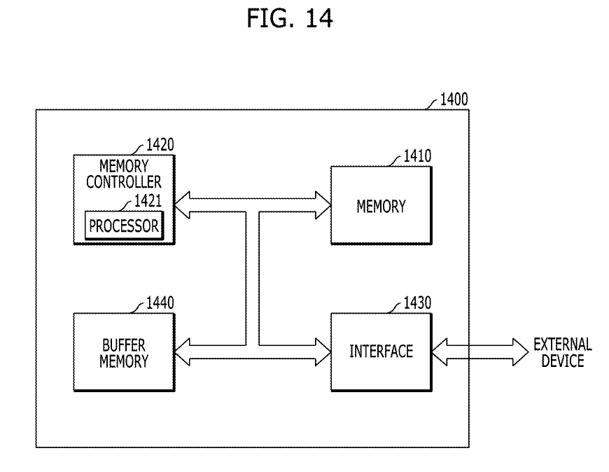

FIG. 14 is an example of configuration diagram of a memory system implementing memory circuitry based on the disclosed technology.

Referring to FIG. 14, a memory system 1400 may include a memory 1410 which has a nonvolatile characteristic as a component for storing data, a memory controller 1420 which controls the memory 1410, an interface 1430 for connection with an external device, and so on. The memory system 1400 may be a card type such as a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory 1410 for storing data may include one or more of the above-described semiconductor devices in accordance with the implementations. For example, the memory 1410 may include a semiconductor substrate having an isolation trench in a first region and a capacitor trench in a second region; an isolation layer filling the isolation trench; an insulation layer pattern disposed along the capacitor trench; and a conductive layer pattern filling the capacitor trench over the insulation layer pattern, wherein a capacitor includes a first portion of the semiconductor substrate in the second region, the insulation layer pattern, and the conductive pattern, and wherein a sidewall of the capacitor trench has a first angle with respect to a surface of the semiconductor substrate and a sidewall of the isolation trench has a second angle with respect to the surface of the semiconductor substrate, the first angle being more proximate to 90 degrees than the second angle. Through this, both an isolation layer characteristic and a capacitor characteristic of the memory 1410 may be satisfied. As a consequence, operating characteristics and data storage characteristics of the memory system 1400 may be improved.

Also, the memory 1410 according to the present implementation may further include a ROM (read only memory), a NOR flash memory, a NAND flash memory, a phase change random access memory (PRAM), a resistive random access memory (RRAM), a magnetic random access memory (MRAM), and so on, which have a nonvolatile characteristic.

The memory controller 1420 may control exchange of data between the memory 1410 and the interface 1430. To this end, the memory controller 1420 may include a processor 1421 for performing an operation for and processing commands inputted through the interface 1430 from an outside of the memory system 1400.

The interface 1430 is to perform exchange of commands and data between the memory system 1400 and the external device. The interface 1430 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. The interface 1430 may be compatible with one or more interfaces having a different type from each other.

The memory system 1400 according to the present implementation may further include a buffer memory 1440 for efficiently transferring data between the interface 1430 and the memory 1410 according to diversification and high performance of an interface with an external device, a memory controller and a memory system. For example, the buffer memory 1440 for temporarily storing data may include one or more of the above-described semiconductor devices in accordance with the implementations. The buffer memory 1440 may include a semiconductor substrate having an isolation trench in a first region and a capacitor trench in a second region; an isolation layer filling the isolation trench; an insulation layer pattern disposed along the capacitor trench; and a conductive layer pattern filling the capacitor trench over the insulation layer pattern, wherein a capacitor includes a first portion of the semiconductor substrate in the second region, the insulation layer pattern, and the conductive pattern, and wherein a sidewall of the capacitor trench has a first angle with respect to a surface of the semiconductor substrate and a sidewall of the isolation trench has a second angle with respect to the surface of the semiconductor substrate, the first angle being more proximate to 90 degrees than the second angle. Through this, both an isolation layer characteristic and a capacitor characteristic of the buffer memory 1440 may be satisfied. As a consequence, operating characteristics and data storage characteristics of the memory system 1400 may be improved.

Moreover, the buffer memory 1440 according to the present implementation may further include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic. Unlike this, the buffer memory 1440 may not include the semiconductor devices according to the implementations, but may include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

Features in the above examples of electronic devices or systems in FIGS. 10-14 based on the memory devices disclosed in this document may be implemented in various devices, systems or applications. Some examples include mobile phones or other portable communication devices, tablet computers, notebook or laptop computers, game machines, smart TV sets, TV set top boxes, multimedia servers, digital cameras with or without wireless communication functions, wrist watches or other wearable devices with wireless communication capabilities.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described. Other implementations, enhancements and variations can be made based on what is described and illustrated in this patent document without departing from the spirit and scope of the invention as defined in the following claims.

What is claimed is:

1. An electronic device comprising a semiconductor memory, the semiconductor memory including:
a semiconductor substrate having an isolation trench in a first region and a capacitor trench in a second region;
an isolation layer filling the isolation trench;
an insulation layer pattern disposed along the capacitor trench; and
a conductive layer pattern filling the capacitor trench over the insulation layer pattern,
wherein a capacitor includes a first portion of the semiconductor substrate in the second region, the insulation layer pattern, and the conductive pattern, and
wherein a sidewall of the capacitor trench has a first angle with respect to a surface of the semiconductor substrate and a sidewall of the isolation trench has a second angle with respect to the surface of the semiconductor substrate, the first angle being more proximate to 90 degrees than the second angle.

2. The electronic device according to claim 1, wherein upper edges of the capacitor trench are more rounded than upper edges of the isolation trench.

3. The electronic device according to claim 1, wherein a bottom surface of the capacitor trench is disposed lower than a bottom surface of the isolation trench.

4. The electronic device according to claim 1, wherein the isolation trench has a width that decreases when it approaches from a top surface to a bottom surface of the isolation trench, and
wherein the capacitor trench has a substantially uniform width along a direction from a top surface to a bottom surface of the capacitor trench.

5. The electronic device according to claim 1, wherein the semiconductor memory further includes:
a gate insulation layer and a gate electrode disposed over a second portion of the semiconductor substrate in the first region.

6. The electronic device according to claim 5, wherein the gate insulation layer includes the same material as the insulation layer pattern, and the gate electrode includes the same material as the conductive layer pattern, and
wherein bottom and top surfaces of the gate insulation layer are substantially coplanar with bottom and top surfaces of the insulation layer pattern, respectively, and bottom and top surfaces of the gate electrode are substantially coplanar with bottom and top surfaces of the conductive layer pattern, respectively.

7. The electronic device according to claim 5, wherein the semiconductor memory further includes:
a first contact plug coupled to the gate electrode and disposed over the gate electrode; and
a second contact plug coupled to the conductive layer pattern and disposed over the conductive layer pattern.

8. The electronic device according to claim 7, wherein the first and second contact plugs include the same material, and
wherein bottom and top surfaces of the first contact plug are substantially coplanar with bottom and top surfaces of the second contact plug, respectively.

9. A method for fabricating an electronic device including a semiconductor memory, the method comprising:
providing a semiconductor substrate having a first region and a second region;
forming an isolation trench and an initial capacitor trench in the first and second regions, respectively, by selectively etching the semiconductor substrate;
forming an isolation layer and a sacrificial layer by filling the isolation trench and the initial capacitor trench, respectively, with an insulation material;
removing the sacrificial layer using a mask pattern that covers the isolation layer in the first region and exposes the sacrificial layer in the second region, a portion of the semiconductor in the second region being exposed by removing the sacrificial layer;
forming a capacitor trench by etching the exposed portion of the semiconductor substrate, the capacitor trench having a sidewall that forms a first angle with respect to a top surface of the semiconductor substrate, the isolation trench having a sidewall that forms a second angle with respect to the top surface of the semiconductor substrate, the first angle being more proximate to 90 degrees than the second angle;
forming an insulation layer along the capacitor trench; and
forming a conductive layer over the insulation layer.

10. The method according to claim 9, wherein forming the isolation trench and the initial capacitor trench includes performing a dry etch process on the semiconductor substrate, each of the isolation trench and the initial capacitor trench having a width that decreases as it approaches from a top surface to a bottom surface of a corresponding one of the isolation trench and the initial capacitor trench.

11. The method according to claim 9, wherein forming the capacitor trench includes performing a blanket etch process to etch a bottom portion of the exposed portion of the semiconductor substrate at a first etching rate and etch an upper portion of the exposed portion at a second etching rate, the first etching rate being higher than the second etching rate.

12. The method according to claim 9, wherein upper edges of the capacitor trench are more rounded than upper edges of the initial capacitor trench.

13. The method according to claim 9, wherein a bottom surface of the capacitor trench is disposed lower than a bottom surface of the initial capacitor trench.

14. The method according to claim 9, further comprising:
removing the mask pattern after forming the capacitor trench and before forming the insulation layer,
wherein the insulation layer and the conductive layer are formed over a substantially entire surface of the semiconductor substrate in the first and second regions.

15. The method according to claim 14, further comprising:
forming a gate pattern in the first region by selectively etching the conductive layer and the insulation layer in the first region after forming the insulation layer and the conductive layer.

16. The method according to claim 15, further comprising:
forming a first contact plug and a second contact plug after forming the gate pattern, the first and second contact plugs being coupled to first and second portions of the conductive layer in the first region and second region, respectively.

17. The method according to claim 9, wherein the forming of the isolation layer and the sacrificial layer includes performing a high aspect ratio process (HARP).

18. The method according to claim 9, wherein forming the insulation layer includes performing a thermal oxidation process.
